(19) United States
(12) Patent Application Publication
(10) Pub. No.: US 2025/0301571 A1
(43) Pub. Date: Sep. 25, 2025

(54) ELECTRONIC DEVICE AND MANUFACTURING METHOD THEREOF

(71) Applicant: Innolux Corporation, Miaoli County (TW)

(72) Inventors: Kun-Teng Ke, Miaoli County (TW); Mei-Yen Chen, Miaoli County (TW); Chung-Chun Cheng, Miaoli County (TW); Wei-Yuan Cheng, Miaoli County (TW); Ker-Yih Kao, Miaoli County (TW)

(73) Assignee: Innolux Corporation, Miaoli County (TW)

(21) Appl. No.: 19/063,253

(22) Filed: Feb. 25, 2025

Related U.S. Application Data
(60) Provisional application No. 63/567,941, filed on Mar. 21, 2024.

(30) Foreign Application Priority Data
Sep. 12, 2024 (CN) 202411280050.X

(51) Int. Cl. H05K 1/14; H05K 3/28

(52) U.S. Cl. CPC H05K 1/14; H05K 3/284; H05K 2201/09218; H05K 2203/1316

(57) ABSTRACT

A manufacturing method of the electronic device includes the following steps. A first electronic unit and a second electronic unit are provided on a carrier. An insulating layer is provided to surround the first electronic unit and the second electronic unit. The insulating layer is grinded to expose at least a portion of the first electronic unit and at least a portion of the second electronic unit. An offset verification is performed on at least one of the first electronic unit and the second electronic unit to obtain an offset result. A circuit structure is provided on the insulating layer according to the offset result. The circuit structure includes a first conductor layer and a second conductor layer. The first conductor layer includes a first trace and a second trace, and the first trace and the second trace are electrically connected via the second conductor layer.

### CROSS-REFERENCE TO RELATED APPLICATION

This application claims the priority benefit of U.S. provisional application Ser. No. 63/567,941, filed on Mar. 21, 2024 and China application serial no. 202411280050.X, filed on Sep. 12, 2024. The entirety of each of the above-mentioned patent applications is hereby incorporated by reference herein and made a part of this specification.

### BACKGROUND

### Technical Field

The disclosure relates to an electronic device and a manufacturing method thereof, and more particularly, to an electronic device having better electrical reliability and a manufacturing method thereof.

### Description of Related Art

In a packaging process, such as a wafer-level package (WLP) process or a panel-level package (PLP) process, since large-area packaging is affected by the die-bond and molding processes, each die may have different offset conditions, which in turn makes the electrical reliability of the product unsatisfactory. In prior art, the size of the annular ring (AR) is increased to cope with the offset of the die while the trace remains unchanged. However, the above method takes up more circuit design space, resulting in a decrease in product competitiveness.

### SUMMARY

The disclosure is directed to an electronic device and a manufacturing method thereof that may have better electrical reliability.

According to an embodiment of the disclosure, a manufacturing method of an electronic device includes the following steps. A first electronic unit and a second electronic unit are provided on a carrier. An insulating layer is provided to surround the first electronic unit and the second electronic unit. The insulating layer is thinned to expose at least a portion of the first electronic unit and at least a portion of the second electronic unit. An offset verification is performed on at least one of the first electronic unit and the second electronic unit to obtain an offset result. A circuit structure is provided on the insulating layer according to the offset result. The circuit structure includes a first conductor layer and a second conductor layer. The first conductor layer includes a first trace and a second trace, and the first trace and the second trace are electrically connected via the second conductor layer.

According to an embodiment of the disclosure, an electronic device includes a first electronic unit and a second electronic unit, an insulation layer, and a circuit structure. The first electronic unit and the second electronic unit are adjacent to each other. The insulating layer surrounds the first electronic unit and the second electronic unit. The circuit structure is disposed on the insulating layer. The circuit structure includes a first conductor layer and a second conductor layer. The first conductor layer includes a first trace and a second trace. The first trace and the second trace are electrically connected via the second conductor layer.

Based on the above, in an embodiment of the disclosure, first, the position (such as offset) of the electronic unit is calculated and confirmed via an algorithm, and the circuit structure is configured using the position information, wherein the second conductor layer may connect the first trace and the second trace of the first conductor layer, so that the electronic device may have better electrical reliability. In addition, the second conductor layer may also be provided without changing the design of the annular ring (AR), or with a design of slightly changing the annular ring (AR), so that the space utilization of the circuit design may be more flexible, thereby improving the competitiveness of the electronic device.

In order to make the above-mentioned features and advantages of the disclosure more comprehensible, the following specific embodiments are described in detail with reference to the accompanying drawings.

### BRIEF DESCRIPTION OF THE DRAWINGS

FIG. 1A to FIG. 1E are schematic cross-sectional views of a manufacturing method of an electronic device of an embodiment of the disclosure.

FIG. 1F is a schematic top view of FIG. 1E.

FIG. 2 is a perspective top view of a plurality of electronic devices on a carrier of an embodiment of the disclosure.

FIG. 3 is a schematic top view of an electronic device of an embodiment of the disclosure.

FIG. 4 is a schematic top view of an electronic device of another embodiment of the disclosure.

FIG. 5A to FIG. 5D are schematic views of a second conductor layer of a circuit structure of a plurality of embodiments of the disclosure.

FIG. 6 is a schematic cross-sectional view of an electronic device of an embodiment of the disclosure.

FIG. 7A is a schematic cross-sectional view of an electronic device of another embodiment of the disclosure.

FIG. 7B is a schematic cross-sectional view of an electronic device of another embodiment of the disclosure.

FIG. 8 is a schematic cross-sectional view of an electronic device of another embodiment of the disclosure.

### DESCRIPTION OF THE EMBODIMENTS

The disclosure may be understood by referring to the following detailed description in conjunction with the accompanying drawings. It should be noted that in order to facilitate understanding to the reader and to simplify the drawings, the plurality of drawings in the disclosure depict a portion of the electronic device, and certain elements in the drawings are not drawn to actual scale. In addition, the quantity and the dimension of each element in the figures are for illustration, and are not intended to limit the scope of the disclosure.

Certain terms are used throughout the specification and the appended claims of the disclosure to refer to particular elements. Those skilled in the art should understand that electronic equipment manufacturers may refer to the same elements under different names. This article does not intend to distinguish between those elements that have the same function but different names.

In the following specification and claims, words such as “containing” and “including” are open-ended words, so they should be interpreted as meaning “containing but not limited to . . . ”

In addition, relative terms, such as “below” or “bottom” and “above” or “top”, may be used in the embodiments to describe the relative relationship of one element of the drawing to another element. It will be understood that if the device in the figures is turned upside down, elements described as being on the “lower” side would then be elements described as being on the “upper” side.

In some embodiments of the disclosure, terms related to joining, connecting, such as “connecting”, “interconnecting”, etc., unless otherwise specified, may mean that two structures are in direct contact, or it may also mean that the two structures are not in direct (indirect) contact, and there are other structures disposed between the two structures. Moreover, the terms of bonding and connecting may also include the case where both structures are movable or both structures are fixed. Moreover, the term “coupling” includes the transfer of energy between two structures via direct or indirect electrical connection, or the transfer of energy between two separate structures via mutual induction.

It should be understood that, when an element or film is referred to as being “on” or “connected to” another element or film, it may be directly on or directly connected to the another element or layer, or there may be an intervening element or layer in between (indirect case). In contrast, when an element is referred to as being “directly on” or “directly connected to” another element or layer, there are no intervening elements or layers present.

The terms “about”, “equal”, “same” or “identical”, “substantially” or “roughly” are generally interpreted as being within 20% of a given value or range, or interpreted as being within 10%, 5%, 3%, 2%, 1%, or 0.5% of a given value or range.

In the disclosure, optical microscopy (OM), scanning electron microscopy (SEM), film thickness profiler (α-step), ellipsometer, or other suitable methods may be used to measure the area, width, thickness, or height of each component, or the distance or pitch between the components. Specifically, according to some embodiments, a scanning electron microscope may be used to obtain a cross-sectional structure image including the components to be measured, and measure the area, width, thickness, or height of each component, or the distance or pitch between the components.

In the disclosure, the definition of roughness determination may be observed by SEM. On an uneven surface, it may be seen that the peaks and valleys of the surface undulation have a distance difference of 0.15 microns (μm) to 1 μm. Measurements of roughness determination may include the use of SEM, transmission electron microscope (TEM), etc. to observe the surface undulation at the same appropriate magnification, and to compare the undulation with a sample of unit length (for example, 10 μm), which is the roughness range thereof. Here, “appropriate magnification” means that at least one surface may have a roughness (Rz) or an average roughness (Ra) of at least 10 undulating peaks visible under the field of view of this magnification.

As used herein, the terms “film” and/or “layer” may refer to any continuous or discontinuous structure and material (such as a material deposited by a method disclosed herein). For example, a film and/or a layer may include a two-dimensional material, a three-dimensional material, a nanoparticle, or even a partial or complete molecular layer, or a partial or complete atomic layer, or a cluster of atoms and/or molecules. The film or layer may include a material or a layer having a pinhole, and may be at least partially continuous.

Although the terms first, second, third . . . may be used to describe various constituent elements, the constituent elements are not limited to these terms. The terms are used to distinguish a single constituent element from other constituent elements in the specification. The same terms may be not used in the claims, but are replaced by first, second, third . . . in the order in which elements are declared in the claims. Therefore, in the following specification, a first constituent element may be a second constituent element in the claims.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having meaning consistent with the background or the context of the related techniques and the disclosure, and should not be interpreted in an idealized or overly formal manner, unless otherwise defined herein.

It should be noted that in the following embodiments, the technical features in several different embodiments may be replaced, recombined, and mixed to complete other embodiments without departing from the spirit of the disclosure.

An electronic device of the disclosure may include a power module, a semiconductor device, a semiconductor packaging device, a display device, an antenna device, a sensing device, a light-emitting device, or a tiling device, but the disclosure is not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system (MEMS), a liquid-crystal chip, etc., but the disclosure is not limited thereto. The diode may include a light-emitting diode or a non-light-emitting diode. The diode includes a P-N junction diode, a PIN diode, or a constant current diode. The LED may include, for example, an organic light-emitting diode (OLED), a mini LED, a micro LED, or a quantum dot light-emitting diode, fluorescence, phosphor, or other suitable materials, or a combination of the above, but the disclosure is not limited thereto. The sensor may include, for example, a capacitive sensor, an optical sensor, an electromagnetic sensor, a fingerprint sensor (FPS), a touch sensor, an antenna, or a pen sensor, but the disclosure is not limited thereto. The following uses a display device as an electronic device to explain the content of the disclosure, but the disclosure is not limited thereto. According to an embodiment of the disclosure, the provided manufacturing method of the electronic device may be applied, for example, to a wafer-level package (WLP) process or a panel-level package (PLP) process, and may adopt a chip-first process or a chip-last (RDL-first) process, which is explained in further detail below. The electronic device referred to in the disclosure may include system on package (SoC), system in package (SiP), antenna in package (AiP), co-packaged optics (CPO), or a combination of the above, but the disclosure is not limited thereto.

Hereinafter, reference will be made in detail to exemplary embodiments of the disclosure, and examples of the exemplary embodiments are illustrated in the figures. Wherever possible, the same reference numerals are used in the drawings and descriptions to refer to the same or like portions.

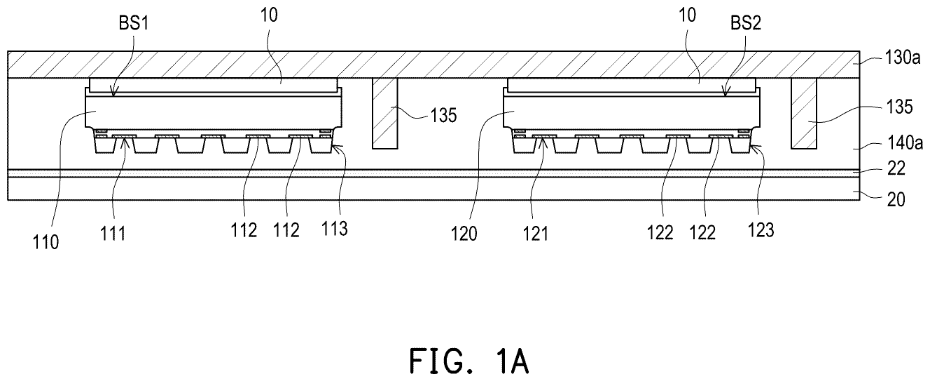

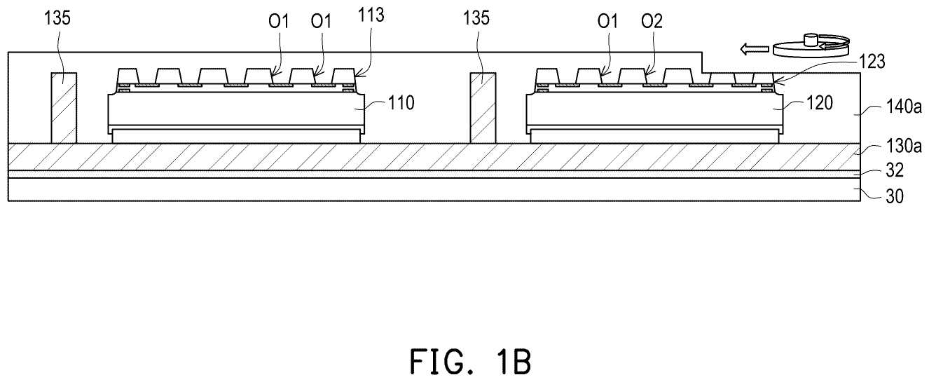

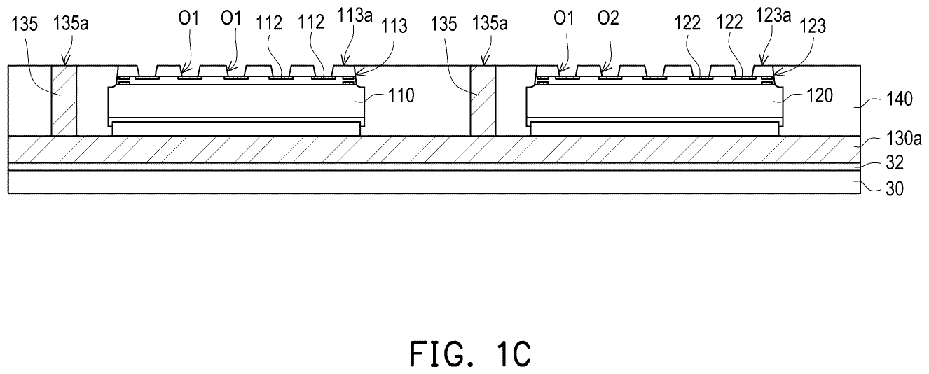

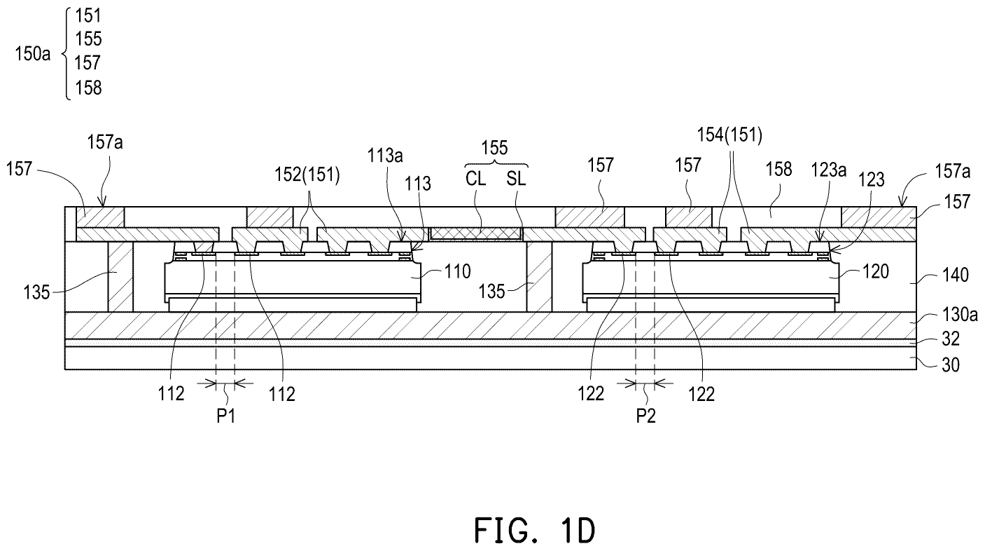

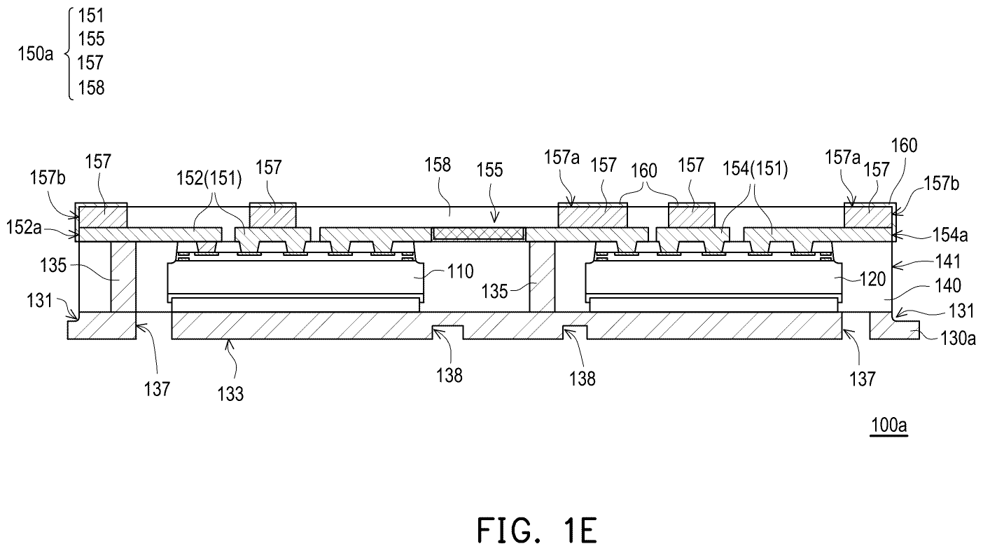

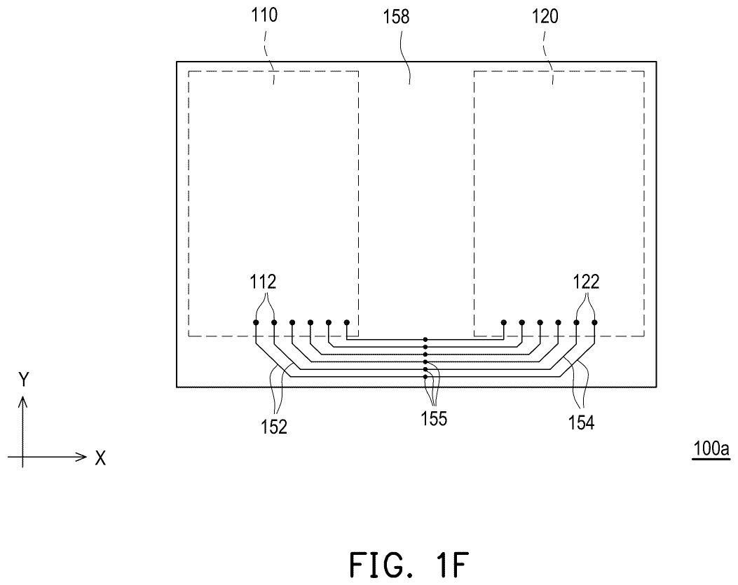

FIG. 1A to FIG. 1E are schematic cross-sectional views of a manufacturing method of an electronic device of an embodiment of the disclosure. FIG. 1F is a schematic top view of FIG. 1E. Please refer to FIG. 1A first. Regarding the manufacturing method of the electronic device of the present embodiment, first, a first electronic unit 110, a second electronic unit 120, and a conductor post 135 are disposed on a temporary carrier (not shown) via a temporary adhesive layer (not shown). Next, an insulating layer 140a is provided to surround the first electronic unit 110, the second electronic unit 120, and the conductor post 135 to form one package structure. Immediately afterwards, a temporary carrier 20 is provided, and the temporary adhesive layer and the temporary carrier are removed. The package structure may be temporarily fixed to the temporary carrier 20 so that a back surface BS1 of the first electronic unit 110, a back surface BS2 of the second electronic unit 120, and a side of the conductor post 135 are away from the temporary carrier 20. Next, a guide plate 130a is provided so that the guide plate 130a is disposed on the back surface BS1 of the first electronic unit 110 and the back surface BS2 of the second electronic unit 120 via an adhesive layer 10, wherein the guide plate 130a may be, for example, a metal plate or a heat dissipation plate, but the disclosure is not limited thereto. The conductor post 135 is suitable for conducting electricity, conducting heat, or conducting both electricity and heat, but the disclosure is not limited thereto, for example, the conductor post 135 comprises metal, ceramic, silicon, grapheme or any suitable materials. In the method described above, the first electronic unit 110 and the second electronic unit 120 are packaged on the temporary carrier in such a manner that a first active surface 111 of the first electronic unit 110 and a second active surface 121 of the second electronic unit 120 are initially away from the temporary carrier, which may be called a face-up process. According to some embodiments, the first electronic unit 110 and the second electronic unit 120 may also be packaged on the temporary carrier with the first active surface 111 of the first electronic unit 110 and the second active surface 121 of the second electronic unit 120 facing the temporary carrier. Then, the back surface BS1 of the first electronic unit 110 and the back surface BS2 of the second electronic unit 120 are exposed, so that the guide plate 130a is disposed at the back surface BS1 of the first electronic unit 110 and the back surface BS2 of the second electronic unit 120 via the adhesive layer 10, which may be called a face-down process.

According to an embodiment, when the chip-down process is adopted, after the package structure is formed via a molding process, and the package structure is turned over, the opening of a first solder mask 113 of the first electronic unit 110 may expose a first input/output pad 112, and a second solder mask 123 of the second electronic unit 120 may expose a second input/output pad 122. When the chip-up process is adopted, the insulating layer 140a is overlapped with the first input/output pad 112, or, the insulating layer 140a and the first solder mask 113 are simultaneously overlapped with the first input/output pad 112 and the second input/output pad 122, and subsequently, a patterning process is needed to expose the first input/output pad 112 and the second input/output pad 122 to facilitate a subsequent process, wherein the patterning step may include yellowing, etching, developing, laser, plasma cleaning, a combination of the above, or other suitable steps, but the disclosure is not limited thereto.

Please refer next to FIG. 1B. FIG. 1B depicts another implementation method. The first electronic unit 110 and the second electronic unit 120 are disposed on the guide plate 130a via the adhesive layer 10. According to some embodiments, the conductor post 135 is also disposed on the guide plate 130a. Furthermore, the conductor post 135 and the guide plate 130a may be integrally formed. According to some embodiments, the conductor post 135 may be additionally formed on the guide plate 130a. The method of forming the conductor post 135 may include chemical plating, electroplating, atomic deposition, chemical deposition, or other suitable process methods, but the disclosure is not limited thereto. Therefore, the difference between the thermal conductivity of the conductor post 135 and the thermal conductivity of the guide plate 130a ranges from 0% to 70% of the thermal conductivity of the guide plate 130a. Immediately afterwards, the insulating layer 140a is provided to surround the first electronic unit 110, the second electronic unit 120, and the conductor post 135, and the insulating layer 140a is directly in contact with an adhesive layer 32 located on a temporary carrier 30. In an embodiment, the temporary carrier 30 may be, for example, a glass substrate, a printed circuit board, a fiberglass (FR4) substrate, a steel substrate, or other suitable substrates, but the disclosure is not limited thereto. In an embodiment, the insulating layer 140a may be, for example, a molding compound, an epoxy resin, other suitable encapsulating materials, or a combination thereof, but the disclosure is not limited thereto. The description of A surrounding B of the disclosure means that a component A is in contact with at least two opposite sides of a component B in a cross-sectional direction. According to some embodiments, the dissociation method of an adhesive layer 22 and the adhesive layer 32 may include photodissociation, thermal dissociation, other suitable methods, or a combination of any two of the above. For example, depending on the different dissociation methods, the adhesive layer 22 and the adhesive layer 32 may be matched with different types of temporary carriers. For example, the adhesive layer 22 and the adhesive layer 32 of the photodissociation type may be used with a transparent glass substrate, and the adhesive layer 22 and the adhesive layer 32 of the thermal dissociation type may be used with a steel plate. The adhesive layer 22 and the adhesive layer 32 may include, for example, ultraviolet (UV) release film, heat release tape (HRT), other suitable materials, or a combination of any two of the above. By disposing the adhesive layer 22 and the adhesive layer 32 on the temporary carrier, the package structure may be effectively separated.

Next, please refer to FIG. 1B and FIG. 1C at the same time, the insulating layer 140a is thinned to expose at least a portion of the first electronic unit 110 and at least a portion of the second electronic unit 120. That is, the thinning method includes removing a portion of the insulating layer 140a by a grinding method, a sandblasting method, a laser method, or other suitable methods, wherein the insulating layer 140a exposes a surface 113a of the first solder mask 113, a surface 123a of the second solder mask 123, and a surface 135a of the conductor post 135. Immediately afterwards, please refer to FIG. 1C again, via a surface treatment procedure such as laser ablation, plasma treatment, or etching, the first solder mask 113 is removed to expose the first input/output pad 112 or the insulating layer 140a located in an opening O1 of the first solder mask 113 is removed to expose the first input/output pad 112, and the second solder mask 123 is removed to expose the second input/output pad 122 or the insulating layer 140a located in an opening O2 of the second solder mask 123 is removed to expose the second input/output pad 122. At this point, the insulating layer 140 surrounding the first electronic unit 110 and the second electronic unit 120 is provided.

Next, referring to FIG. 1D, an offset verification is performed on at least one of the first electronic unit 110 and the second electronic unit 120. According to some embodiments, one of the first electronic unit 110 and the second electronic unit 120 may be designated as the master die by first confirming the size of an annular ring (AR). Generally, the annular ring refers to a dimension the copper ring that is flat on the board surface around the outer wall of the access hole. According to some embodiments, one of the first electronic unit 110 and the second electronic unit 120 may be designated as the master die by first confirming the distance between adjacent annular rings. More specifically, less distance between adjacent annular rings is indicative of a position where the variation allowed in the manufacturing process is less, which may be defined as the master die. In other words, a die that still allows minor variations may be considered the master die depending on the circumstances.

In an embodiment, the first electronic unit 110 includes the first input/output pad 112 having a first pitch P1, and the second electronic unit 120 includes the second input/output pad 122 having a second pitch P2, and when the first pitch P1 is different from the second pitch P2, a die having a smaller pitch is a master die. The following description takes the first electronic unit 110 as the master die as an example to perform an offset verification to obtain an offset result including the position of the electronic unit or the position of the trace, but the disclosure is not limited thereto. Immediately afterwards, the position of the first electronic unit 110 is checked via a detection equipment to obtain the position information of the first electronic unit 110. In an embodiment, the position information includes the position of the first input/output pad 112 of the first electronic unit 110. Then, according to the position information, a first trace 152 is formed on the first electronic unit 110, wherein the first trace 152 is electrically connected to the first input/output pad 112 of the first electronic unit 110, and the orthographic projection of the first trace 152 on the first electronic unit 110 is overlapped with the first electronic unit 110. Next, the position of the second electronic unit 120 is checked via a detection equipment to obtain the position information of the second electronic unit 120. Immediately afterwards, according to the position information, a second trace 154 is formed on the second electronic unit 120, wherein the second trace 154 is electrically connected to the second input/output pad 122 of the second electronic unit 120, and the orthographic projection of the second trace 154 on the second electronic unit 120 is overlapped with the second electronic unit 120. Here, the first trace 152 and the second trace 154 may be defined as the first conductor layer 151, and the first trace 152 is insulated from the second trace 154. In other words, the present embodiment confirms the offsets of the first electronic unit 110 and the second electronic unit 120 respectively, and the first pitch P1 and the second pitch P2 are measured to determine the positions of the first trace 152 and the second trace 154 respectively. Next, the first trace 152 and the second trace 154 are calculated to determine the position of the second conductor layer 155, wherein the first trace 152 and the second trace 154 are electrically connected via the second conductor layer 155. Here, the second conductor layer 155 may be regarded as a compensation pattern that may achieve interconnection requirements between offset electronic units. In an embodiment, the first trace 152, the second trace 154, and the second conductor layer 155 are located on the same plane, but the disclosure is not limited thereto. The first conductor layer 151 and the second conductor layer 155 may be defined as a circuit structure 150a. So far, the circuit structure 150a is provided on the insulating layer 140 according to the offset, wherein the circuit structure 150a may include the first conductor layer 151 and the second conductor layer 155. The first conductor layer 151 includes the first trace 152 and the second trace 154, and the first trace 152 and the second trace 154 are electrically connected via the second conductor layer 155. In some of the embodiment, the first trace 152, the second trace 154 and the second conductor layer 155 would be formed simultaneously or in stages, for example, the methods for forming the first trace 152, the second trace 154 and the second conductor layer 155 including mask-less lithography, but not limited to. In some of the embodiment, the first trace 152, the second trace 154 and the second conductor layer 155 would be co-planer or not.

Please continue to refer to FIG. 1D. In detail, the method of forming the second conductor layer 155 includes determining the position of the second conductor layer 155, and then providing a seed layer SL overlapped with the first trace 152 and the second trace 154, and then providing a conductor layer CL on the seed layer SL, and removing a portion of the seed layer SL, so that the remaining portion of the seed layer SL is disposed between the conductor layer CL, the insulating layer 140a, the first trace 152, and the second trace 154. That is, the seed layer SL and the conductor layer CL define the second conductor layer 155. The method of forming the conductor layer CL and the seed layer SL includes electroplating, chemical plating, deposition, yellow light development, etching, thinning, or other suitable processes, but the disclosure is not limited thereto. The materials of the seed layer SL and the conductor layer CL may include titanium, copper, tantalum, nickel, tungsten, nitride, or a combination of the above, but the disclosure is not limited thereto.

In the present embodiment, the circuit structure 150a may be a redistribution layer (RDL) and includes at least one conductive layer and at least one dielectric layer (FIG. 1 schematically illustrates three conductive layers and two dielectric layers, but the disclosure is not limited thereto). The RDL may redistribute circuits and/or further increase the circuit fan-out area, the RDL may be used to electrically connect different electronic components, the RDL may extend a wire to a wider pitch or reroute a wire to another wire having a different pitch, and/or the RDL may serve as a substrate for routing the electrical interface between one connection and another connection. For example, the pitch of two adjacent contact pads of a redistribution structure in contact with one end of an electronic component may be less than or equal to the pitch of two adjacent contact pads of the redistribution structure away from the end of the electronic component. Therefore, the redistribution structure may adjust the circuit fan-out condition or electrically connect the circuit structure/electronic component having the first pitch to the circuit structure/electronic component having the second pitch, but the disclosure is not limited thereto. In particular, the step of forming the RDL may include providing a stack of at least one conductive layer and at least one dielectric layer, and the method of forming the RDL may include a process such as yellow light, etching, surface treatment, laser, electroplating, chemical plating, deposition, atomic level deposition. In particular, the surface treatment may include roughening or activating the surface of the dielectric layer or the surface of the conductive layer to improve the adhesion ability of the dielectric layer or the conductive layer. For example, by increasing the surface roughness, the bonding force with a subsequent layer may be improved.

In another embodiment, the position information of the master die may be checked. That is, the position of the first input/output pad 112 of the first electronic unit 110 is checked, and the circuit structure 150a is formed with reference to the position information. In other words, in the present embodiment, the offset of the first electronic unit 110 may be confirmed, and the first pitch P1 may be measured to determine the positions of the first trace 152 and the second trace 154, and the position of the second conductor layer 155 may be determined by calculating at least one of the first trace 152 and the second trace 154.

Please refer to FIG. 1D again. After the first conductor layer 151 is formed, a connecting post 157 may also be formed on the first trace 152 and the second trace 154, wherein the connecting post 157 is electrically connected to the first trace 152 and the second trace 154 respectively, so as to said, the first trace 152 and the second trace 154 would be not electrically connected with each other through the connecting post 157. Next, an insulating layer 158 may also be formed to cover the first conductor layer 151, the second conductor layer 155, and the connecting post 157 and expose a surface 157a of the connecting post 157. Here, in addition to including the first conductor layer 151 and the second conductor layer 155, the circuit structure 150a may also include the connecting post 157 and the insulating layer 158.

Next, please refer to FIG. 1D and FIG. 1E at the same time, in which the carrier 30 and the adhesive layer 32 thereon are removed, and a singulation process is performed to at least cut the insulating layer 158 and the insulating layer 140. In an embodiment, a sidewall 157b of the connecting post 157 may be flush with a surrounding surface 141 of the insulating layer 140, but the disclosure is not limited thereto. In an embodiment, a portion of the guide plate 130a may be removed to form a curved surface 131, but the disclosure is not limited thereto. In an embodiment, a portion of the guide plate 130a may be removed to form the guide plate 130a having an opening 137 and/or a groove 138, wherein the opening 137 penetrates the guide plate 130a from a bottom surface 133 toward the direction of the insulating layer 140, and the groove 138 may be formed at the bottom surface 133. Since the guide plate 130a has a patterned design, that is, having the opening 137 and/or the groove 138, cracking of the first electronic unit 110 and the second electronic unit 120 due to large stress may be avoided. Moreover, the guide plate 130a having the opening 137 and/or the groove 138 may improve the subsequent bonding force with a printed circuit board, but not limited to. In some of the embodiments, since the guide plate 130a has a patterned design, that is, having the opening 137 and/or the groove 138, heat dissipation function of the electronic device would be improved. In an embodiment, a connecting layer (not shown) may be disposed on the bottom surface 133 of the guide plate 130a, wherein the material of the connecting layer may be tin, nickel, gold, silver, gallium, or other suitable metal materials, and may be bonded to an external component (such as a printed circuit board) via the connecting layer. Lastly, the connecting member 160 may be formed on the connecting post 157, wherein the connecting member 160 may be extended to cover a sidewall 152a of the first trace 152 and a sidewall 154a of the second trace 154, but the disclosure is not limited thereto. At this point, the manufacture of the electronic device 100a is completed.

It should be noted that in the present embodiment, one electronic device 100a is schematically shown on the carrier 30, but the disclosure is not limited thereto. In an embodiment, a plurality of electronic devices may be disposed on the carrier 30, and the circuit structure may be disposed by checking the position information of the master dies in all electronic devices, or by checking a few areas and taking the average displacement.

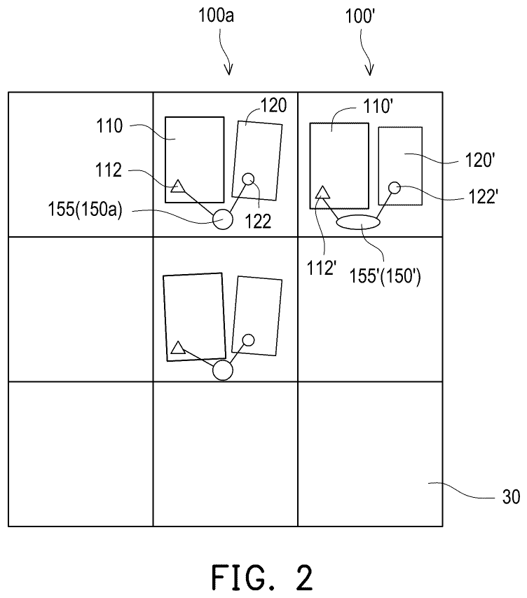

FIG. 2 is a perspective top view of a plurality of electronic devices on a carrier of an embodiment of the disclosure. Please refer to FIG. 2. Circuit structures 150a and 150′ of two adjacent electronic devices 100a and 100′ are different from each other. For example, the size, the position, the shape, etc. of the first input/output pad 112 of the first electronic unit 110 of the electronic device 100a and a first input/output pad 112′ of a first electronic unit 110′ of the electronic device 100′ may be the same, but the disclosure is not limited thereto. The size and the shape of the second input/output pad 122 of the second electronic unit 120 of the electronic device 100a and a second input/output pad 122′ of a second electronic unit 120′ of the electronic device 100′ may be the same, but the positions thereof may be different, but the disclosure is not limited thereto. The size, the position, the shape, etc. of the second conductor layer 155 of the circuit structure 150a of the electronic device 100a and a second conductor layer 155′ of the circuit structure 150′ of the electronic device 100′ may be different, but the disclosure is not limited thereto.

Structurally, please refer to FIG. 1E and FIG. 1F at the same time. In the present embodiment, the electronic device 100a includes the first electronic unit 110 and the second electronic unit 120, the insulating layer 140, and the circuit structure 150a. The first electronic unit 110 and the second electronic unit 120 are arranged adjacent to each other or side by side along a direction (such as direction X) in a cross-section view. The insulating layer 140 surrounds the first electronic unit 110 and the second electronic unit 120 and exposes at least a portion of the first electronic unit 110 and at least a portion of the second electronic unit 120. The circuit structure 150a is disposed on the insulating layer 140, and the circuit structure 150a includes the first conductor layer 151 and the second conductor layer 155. The first conductor layer 151 includes the first trace 152 and the second trace 154. The first trace 152 is insulated from the second trace 154, and the first trace 152 and the second trace 154 are electrically connected via the second conductor layer 155. As shown in FIG. 1F, in the present embodiment, each of the first traces 152 is electrically connected to each of the second traces 154 via one second conductor layer 155, but the disclosure is not limited thereto. In an embodiment, the second conductor layer 155 is, for example, a compensation pattern.

Furthermore, the electronic device 100a of the present embodiment further includes the guide plate 130a, and the first electronic unit 110 and the second electronic unit 120 are disposed on the guide plate 130a. In an embodiment, the first electronic unit 110 and the second electronic unit 120 share the same guide plate 130a, wherein the guide plate 130a may be, for example, a metal plate or a heat sink plate, but the disclosure is not limited thereto. In addition, the electronic device 100a of the present embodiment may further include the conductor post 135 penetrating the insulating layer 140 and connected to the first trace 152 and the guide plate 130a and connected to the second trace 154 and the guide plate 130a. Here, the conductor post 135 is suitable for conducting electricity, conducting heat, or conducting both electricity and heat, but the disclosure is not limited thereto.

In addition, the circuit structure 150a of the present embodiment may also include the connecting post 157 and the insulating layer 158. The connecting post 157 is disposed on the first trace 152 and the second trace 154, wherein the connecting post 157 is electrically connected to the first trace 152 and the second trace 154. The insulating layer 158 covers the first conductor layer 151, the second conductor layer 155, and the connecting post 157, and exposes the surface 157a of the connecting post 157. In addition, the circuit structure 100a of the present embodiment may further include the connecting member 160 disposed on the surface 157a of the connecting post 157, wherein the connecting member 160 may be extended to cover the sidewall 152a of the first trace 152 and the sidewall 154a of the second trace 154, but the disclosure is not limited thereto. For example, the connecting post 157 is functions as the annular ring, so as to said, the connecting post 157 would be contacted with a printed circuit board or another electronic device through a solder ball or any suitable connection element.

In short, in the present embodiment, the position information of the master die, such as the position (such as offset) of the first electronic unit 110 is first calculated and confirmed via an algorithm, thereby disposing the first conductor layer 151, and then the position of the second conductor layer 155 is determined by calculating the first conductor layer 151, so that the second conductor layer 155 is connected to the first trace 152 and the second trace 154 of the first conductor layer 151. In this way, the electronic device 100a may have better electrical reliability. Moreover, the arrangement of the second conductor layer 155 also eliminates the need to change the size of the annular ring (AR), so that space utilization of the circuit design is more flexible, thereby enhancing the competitiveness of the electronic device 100a of the present embodiment.

It should be noted here that the following embodiments adopt the reference numerals and a portion of the content of the above embodiments, wherein the same reference numerals are used to represent the same or similar elements, and the description of the same technical content is omitted. For descriptions of omitted portions, reference may be made to the above embodiments and are not repeated in the following embodiments.

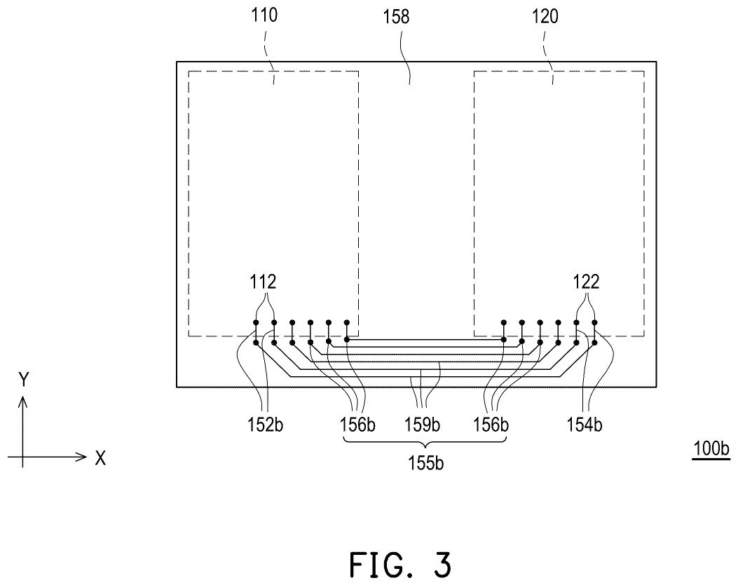

FIG. 3 is a schematic top view of an electronic device of an embodiment of the disclosure. Please refer to FIG. 1F and FIG. 3 at the same time. An electronic device 100b of the present embodiment is similar to the electronic device 100a of FIG. 1F. The difference between the two is that in the present embodiment, a second conductor layer 155b includes a compensation pattern 156b and a compensation trace 159b connected to each other. Each first trace 152b is electrically connected to each second trace 154b via two compensation patterns 156b and one compensation trace 159b, but the disclosure is not limited thereto.

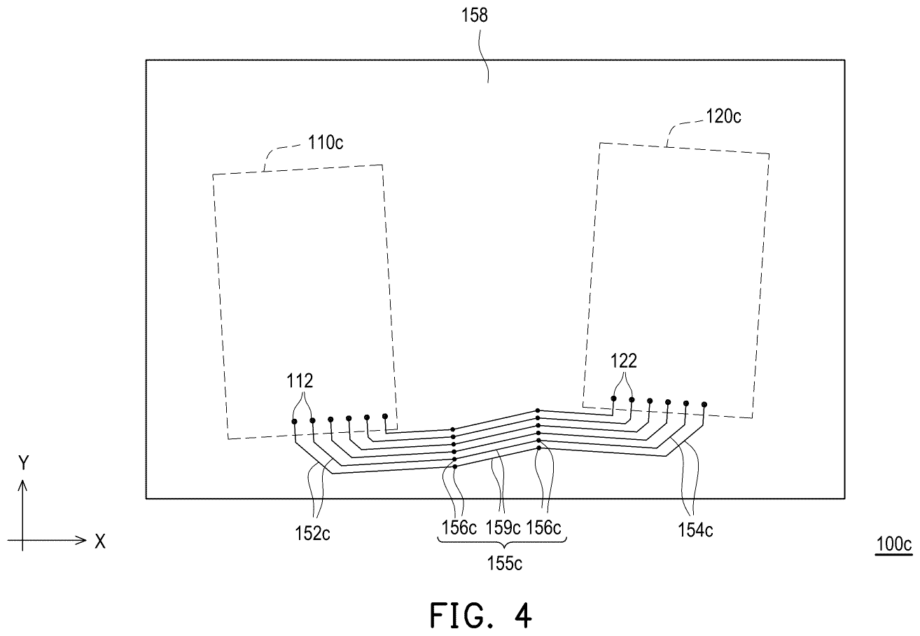

FIG. 4 is a schematic top view of an electronic device of another embodiment of the disclosure. Please refer to FIG. 1 and FIG. 4 at the same time. An electronic device 100c of the present embodiment is similar to the electronic device 100a of FIG. 1F. The difference between the two is that in the present embodiment, a first electronic unit 110c and a second electronic unit 120c are arranged in an offset manner. A second conductor layer 155c includes a compensation pattern 156c and a compensation trace 159c connected to each other. Each first trace 152c is electrically connected to each second trace 154c via two compensation patterns 156c and one compensation trace 159c, but the disclosure is not limited thereto.

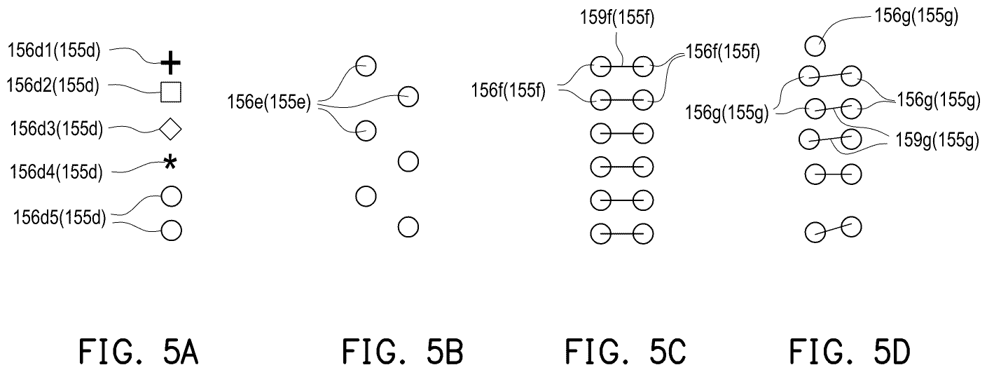

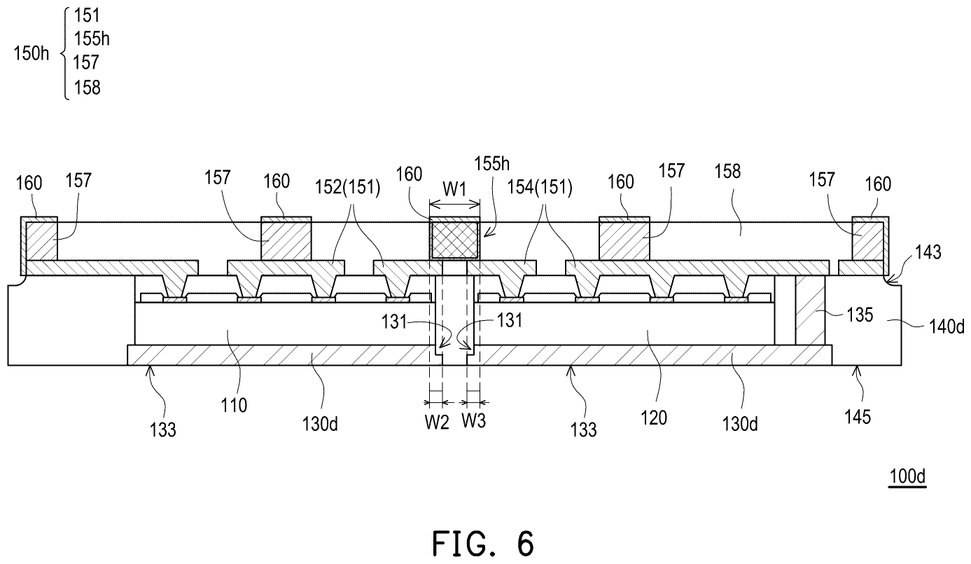

It should be noted that the disclosure does not limit the structural type of the second conductor layer, that is, the disclosure does not limit the arrangement method of the compensation patterns and the compensation traces. FIG. 5A to FIG. 5D are schematic views of a second conductor layer of a circuit structure of a plurality of embodiments of the disclosure.

Please refer to FIG. 5A first. A second conductor layer 155d includes a plurality of compensation patterns 156d1, 156d2, 156d3, 156d4, and 156d5, wherein the compensation patterns 156d1, 156d2, 156d3, 156d4, and 156d5 are arranged at equal intervals, but the disclosure is not limited thereto. Viewed from above, the shape of the compensation pattern 156d1 may be a cross; the shape of the compensation pattern 156d2 may be a square; the shape of the compensation pattern 156d3 may be a rhombus; the shape of the compensation pattern 156d4 may be a snowflake; and the shape of the compensation pattern 156d5 may be a circle, but the disclosure is not limited thereto.

Referring to FIG. 5B, a second conductor layer 155e includes a plurality of compensation patterns 156e, wherein the compensation patterns 156e are arranged in a staggered manner, but the disclosure is not limited thereto.

Please refer to FIG. 5C. A second conductor layer 155f includes a plurality of compensation patterns 156f and a plurality of compensation traces 159f, wherein one compensation trace 159f connected to two compensation patterns 156f may be regarded as a set of connecting structures, and the connecting structures may be arranged at equal intervals, but the disclosure is not limited thereto.

Please refer to FIG. 5D. A second conductor layer 155g includes a plurality of compensation patterns 156g and a plurality of compensation traces 159g, wherein a portion of the compensation patterns 156g may be disposed independently without being connected to the compensation traces 159g, and one compensation trace 159g connected to two compensation patterns 156g may be regarded as a set of connecting structures, and the connecting structures may be non-array and non-equally spaced, but the disclosure is not limited thereto.

In short, in the disclosure, the second conductor layer may be in any shape, wherein the arrangement method of the second conductor layer may be a matrix arrangement, a non-matrix arrangement, an equal pitch arrangement, or a non-equal pitch arrangement, etc., but the disclosure is not limited thereto. The position and the size of the second conductor layer may be known by calculation via algorithm and software processing. The second conductor layer may be variable both in shape and position, variable in size, or variable both in size and position.

FIG. 6 is a schematic cross-sectional view of an electronic device of an embodiment of the disclosure. Please refer to FIG. 1 and FIG. 6 at the same time. An electronic device 100d of the present embodiment is similar to the electronic device 100a of FIG. 1E. The difference between the two is that in the present embodiment, a second conductor layer 155h of a circuit structure 150h is connected across the first trace 152 and the second trace 154. Specifically, the second conductor layer 155h is located on the first trace 152 and the second trace 154, the second conductor layer 155h has a first width W1, the overlap between the second conductor layer 155h and the first trace 152 has a second width W2, and the overlap between the second conductor layer 155h and the second trace 154 has a third width W3, wherein the ratio of the second width W2 to the first width W1 or the ratio of the third width W3 to the first width W1 is between 0.3 and 0.7. In addition, in the present embodiment, the first electronic unit 110 and the second electronic unit 120 are respectively disposed on two guide plates 130d, wherein the guide plates 130d are separated from each other and have a curved surface 131 respectively, but the disclosure is not limited thereto. An insulating layer 140d surrounds the first electronic unit 110, the second electronic unit 120, the at least one guide plate 130d and the conductor post 135 and has a curved surface 143 adjacent to the connecting member 160, wherein a bottom surface 145 of the insulating layer 140d exposes the bottom surface 133 of the guide plates 130d to increase heat dissipation effect. In detail to said, the bottom surface 145 is away from the circuit structure 150. The electronic device 100 could be bonded with another electronic device or circuit board by the connecting member 160, a under fill layer would be disposed between the electronic device 100 and another electronic device or circuit board, a portion of the under fill layer would be in contacted with the curved surface 143, and a bonding strength between the electronic device 100 with another electronic or circuit board will be improved, wherein a material of the under fill layer including organic material, but not limited to.

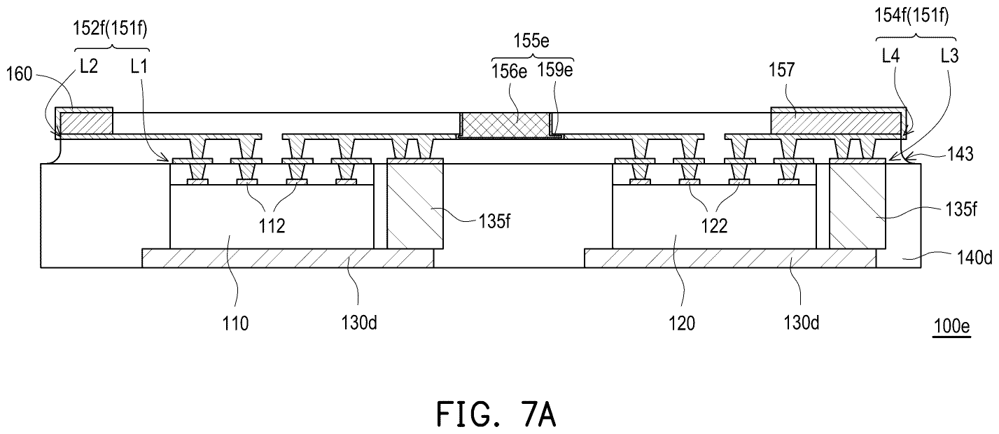

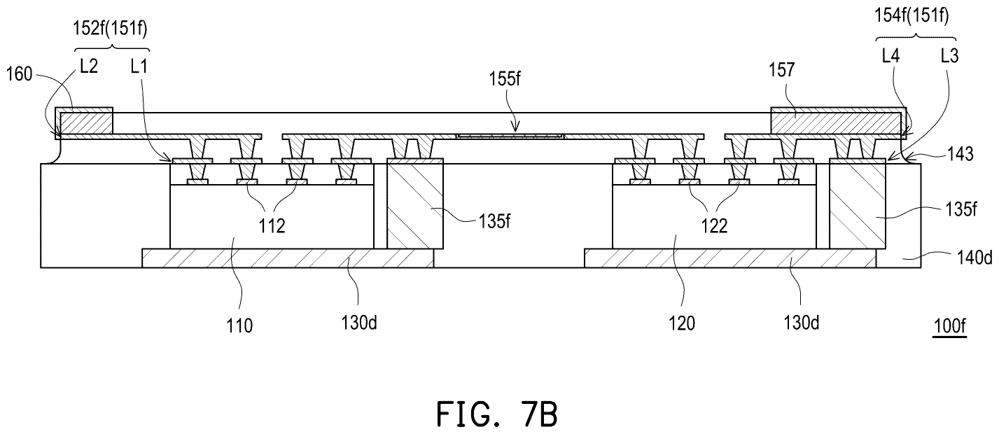

FIG. 7A is a schematic cross-sectional view of an electronic device of another embodiment of the disclosure. Please refer to FIG. 6 and FIG. 7 at the same time. An electronic device 100e of the present embodiment is similar to the electronic device 100d of FIG. 6. The difference between the two is that in the present embodiment, a first trace 152f and a second trace 154f of a first conductor layer 151f respectively have a plurality of circuit layers. Specifically, in the present embodiment, the first trace 152f includes a circuit layer L1 and a circuit layer L2, wherein the circuit layer L1 is electrically connected to the first input/output pad 112 of the first electronic unit 110, and the circuit layer L2 is located on the circuit layer L1 and electrically connected to the circuit layer L1. In an embodiment, the first trace 152f is, for example, a fan-out trace, but the disclosure is not limited thereto. The second trace 154f includes a circuit layer L3 and a circuit layer L4, wherein the circuit layer L3 is electrically connected to the second input/output pad 122 of the second electronic unit 120, and the circuit layer L4 is located on the circuit layer L3 and electrically connected to the circuit layer L3. In an embodiment, the second trace 154f is, for example, a fan-out trace, but the disclosure is not limited thereto. Furthermore, in the present embodiment, a conductor post 135f is connected to the circuit layer L1 of the first trace 152f and the metal plate 130d and connected to the circuit layer L3 of the second trace 154f and the metal plate 130d. In addition, the second conductor layer 155e includes the compensation pattern 156e and a compensation trace 159e, wherein the compensation trace 159e is connected to the circuit layer L2 of the first trace 152f and the circuit layer L4 of the second trace 154f, and the compensation pattern 156e are located on the compensation trace 159e and connected to the compensation trace 159e. A material of the compensation pattern 156e including Ti, Cu, W, Al, Ga, AlN, TiN or any suitable materials, and a material of the compensation trace 159e including Cu, Al, Ni, Au or any suitable materials.

FIG. 7B is a schematic cross-sectional view of an electronic device of another embodiment of the disclosure. Please refer to FIG. 7A and FIG. 7B at the same time. An electronic device 100f of the present embodiment is similar to the electronic device 100e of FIG. 7A. The difference between the two is that in the present embodiment, the second conductor layer 155f is connected to the circuit layer L2 of the first trace 152f and the circuit layer L4 of the second trace 154f, and located on the same plane as the circuit layer L2 and the circuit layer L4, but the disclosure is not limited thereto.

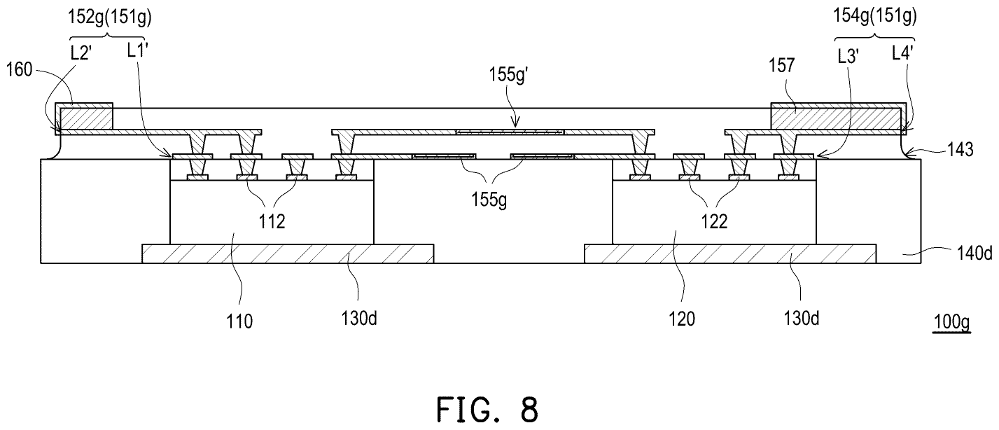

FIG. 8 is a schematic cross-sectional view of an electronic device of another embodiment of the disclosure. Please refer to FIG. 7B and FIG. 8 at the same time. An electronic device 100g of the present embodiment is similar to the electronic device 100f of FIG. 7B. The difference between the two is that in the present embodiment, a first trace 152g and a second trace 154g of a first conductor layer 151g respectively have a plurality of circuit layers, the first trace 152g and the second trace 154g is electrically connected with each other by the second conductor layer 155g according to the design. In fact, during the manufacturing method of an electronic device 100g, the second conductor layer 155g is open or comprises defect, then calculating the first trace 152g and the second trace 154g again to determine a position of the second conductor layer 155g′, after repairing, the first trace 152g and the second trace 154g is electrically connected with each other by the second conductor layer 155g′. The circuit layer L1′ of the first trace 152g and the circuit layer L3′ of the second trace 154g are disposed on the same plane, wherein the circuit layer L1′ extends outside the first electronic unit 110, the circuit layer L3′ extends outside the second electronic unit 120, and the circuit layer L1′ and the circuit layer L3′ are not connected to each other. The second conductor layer 155g is connected to the circuit layer L2′ of the first trace 152g and the circuit layer L4′ of the second trace 154g, and located on the same plane as the circuit layer L2′ and the circuit layer L4′, but the disclosure is not limited thereto.

It should be noted that in an embodiment, the electronic device may not include the guide plate. That is, the insulating layer directly covers the back surface of the electronic unit relative to the active surface, or the insulating layer may directly expose the back surface of the electronic unit, which is still within the scope of the disclosure.

Based on the above, first, the position (such as offset) of the electronic unit is calculated and confirmed via an algorithm, and the circuit structure is configured using the position information, wherein the second conductor layer may connect the first trace and the second trace of the first conductor layer, so that the electronic device may have better electrical reliability. Moreover, the arrangement of the second conductor layer also eliminates the need to change the size of the annular ring (AR), so that space utilization of the circuit design is more flexible, thereby enhancing the competitiveness of the electronic device.

Lastly, it should be noted that the above embodiments are used to describe the technical solution of the disclosure instead of limiting it. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

What is claimed is:

1. A manufacturing method of an electronic device, comprising:
providing a first electronic unit and a second electronic unit on a carrier;
providing an insulating layer to surround the first electronic unit and the second electronic unit;
thinning the insulating layer to expose at least a portion of the first electronic unit and at least a portion of the second electronic unit;
performing an offset verification on at least one of the first electronic unit and the second electronic unit to obtain an offset result; and
providing a circuit structure on the insulating layer according to the offset result, wherein the circuit structure comprises a first conductor layer and a second conductor layer, the first conductor layer comprises a first trace and a second trace, and the first trace and the second trace are electrically connected via the second conductor layer.

2. The manufacturing method of the electronic device of claim 1, further comprising:
calculating at least one of the first trace and the second trace to determine a position of the second conductor layer.

3. The manufacturing method of the electronic device of claim 1, further comprising:
the first electronic unit comprises a first input/output pad having a first pitch, and the second electronic unit comprises a second input/output pad having a second pitch, and when the first pitch is different from the second pitch, at least a smaller of the first pitch and the second pitch is measured to determine positions of the first trace and the second trace.

4. An electronic device, comprising:
a first electronic unit and a second electronic unit adjacent to each other;
an insulating layer surrounding the first electronic unit and the second electronic unit; and
a circuit structure disposed on the insulating layer, wherein the circuit structure comprises a first conductor layer and a second conductor layer, the first conductor layer comprises a first trace and a second trace, and the first trace and the second trace are electrically connected via the second conductor layer.

5. The electronic device of claim 4, wherein the first trace is insulated from the second trace.

6. The electronic device of claim 4, wherein the second conductor layer is located on the first trace and the second trace, the second conductor layer has a first width, an overlap between the second conductor layer and the first trace has a second width, an overlap between the second conductor layer and the second trace has a third width, and a ratio of the second width to the first width or a ratio of the third width to the first width is between 0.3 and 0.7.

7. The electronic device of claim 4, wherein the circuit structures of two adjacent electronic devices are different from each other.

8. The electronic device of claim 4, further comprising:
at least one guide plate, wherein the first electronic unit and the second electronic unit are disposed on the at least one guide plate.

9. The electronic device of claim 8, further comprising:
a conductor post penetrating the insulating layer and connected to at least one of the first trace and the second trace and the at least one guide plate.

10. The electronic device of claim 8, wherein the at least one guide plate has an opening and a groove, the opening penetrates the at least one guide plate from a bottom surface toward the insulating layer, and the groove is located at the bottom surface.

11. The electronic device of claim 8, wherein the at least one guide plate comprises a metal plate or a heat sink plate.

12. The electronic device of claim 8, wherein the insulating layer surrounds the at least one guide plate, and a bottom surface of the insulating layer away from the circuit structure exposes a bottom surface of the at least one guide plate.

13. The electronic device of claim 4, wherein the circuit structure further comprises a connecting post disposed on the first trace and the second trace respectively.

14. The electronic device of claim 13, wherein the circuit structure further comprises a connecting member disposed on a surface of the connecting post and extended to cover a sidewall of the first trace and a sidewall of the second trace.

15. The electronic device of claim 4, wherein the second conductor layer comprises a compensation pattern and a compensation trace connected to each other, and the first trace is electrically connected to the second trace via two of the compensation patterns and the compensation trace.

16. The electronic device of claim 15, wherein the first electronic unit and the second electronic unit are arranged in an offset manner.

17. The electronic device of claim 15, wherein when viewed from above, a shape of the compensation pattern comprises a cross, a square, a rhombus, a snowflake, or a circle.

18. The electronic device of claim 4, wherein the first trace and the second trace of the first conductor layer respectively comprise a plurality of circuit layers.

19. The electronic device of claim 4, wherein the insulating layer comprises a molding compound, an epoxy resin, or a combination thereof.

20. The electronic device of claim 4, wherein the first electronic unit comprises a first input/output pad having a first pitch, and the second electronic unit comprises a second input/output pad having a second pitch, and when the first pitch is different from the second pitch, a die having a smaller pitch is a master die.
